(19) United States
(12) Patent Application Publication
(10) Pub. No.: US 2006/0028217 A1
(43) Pub. Date: Feb. 9, 2006

(54) System of detection and repair and method thereof

(75) Inventors: Meng-Chieh Liao, Hsinchu (TW); Chi-Chung Chen, Taipei (TW)

Correspondence Address: BIRCH STEWART KOLASCH & BIRCH, PO BOX 747, FALLS CHURCH, VA, 22040-0747, US

(73) Assignee: RiTdisplay Corporation

(21) Appl. No.: 11/180,712

(22) Filed: Jul. 14, 2005

(30) Foreign Application Priority Data
Jul. 15, 2004 (TW) 093121198

(51) Int. Cl. G01R 31/305; H01J 9/50

(52) U.S. Cl. 324/751; 445/2

(57) ABSTRACT

A system of detection and repair is to detect and repair an organic electroluminescent apparatus. When detecting locations of defects, the system charges a bias to the detected locations of the organic electroluminescent apparatus. A detector, such as an infrared (IR) detector, of the system detects the locations of defects having abnormal current distribution. A beam generator of the system is then used to generate a beam for isolating the defects. A method of detection and repair is further provided.

### BACKGROUND OF THE INVENTION

1. Field of Invention

The invention relates to a system and a method of detection and repair and, in particular, to a system and method for detecting and repairing defects of an organic electroluminescent apparatus.

2. Related Art

Information communication technology has become a major focus of the industry, especially the portable communication display products which are the point of development. Flat panel displays provide an interface between humans and information, thus they have become an important development direction of manufacturers. Present choices of flat panel displays include the plasma display panel (PDP), liquid crystal display (LCD), inorganic electroluminescence display (ELD), light-emitting diode (LED) display, vacuum fluorescence displays (VFD), field emission displays (FED), electro-chromic display, and the likes.

Compared to other flat panel displays, organic electroluminescent apparatuses, such as organic electroluminescent panels or organic electroluminescent devices, are self-emissive, and possess the advantages of full viewing angle, high power efficiency, easy manufacture, low cost, rapid response, and full color. Therefore, organic electroluminescent apparatuses may become the major choice for flat panel display technology in the future.

The organic electroluminescent apparatuses utilize the self-emissive properties of specific organic functional materials to achieve the objective of displaying. According to the different molecular weights of the organic functional materials, the organic electroluminescent apparatuses are classified into the small molecule OLED (SM-OLED) and the polymer light-emitting device (PLED). When applying the current to the two electrodes, the electrons and holes move and recombine in the organic functional material layer to generate excitons. The organic functional material layer can then radiate light of different colors according to their characteristics.

If particles exist on a pixel of the organic electroluminescent apparatus during manufacture thereof, the multiple layers of the pixel may be stacked abnormally. Additionally, the electrodes of the organic electroluminescent apparatus may contact each other and short-circuit. Consequently, the brightness, the quality and reliability of the organic electroluminescent apparatus are-decreases. Thus, it is critical to detect and repair the defects of products to ensure the quality.

To solve the above-mentioned problem, the person of ordinary skill in the art usually utilizes a detection machine with an optical microscope and a repairing machine having a beam generator to detect and repair an organic electroluminescent apparatus.

In the conventional detection process, a detection machine scans an organic electroluminescent apparatus to determine whether each pixel of the organic electroluminescent apparatus has a defect or not, and then positions the location of the defect. In a subsequent step, the defective organic electroluminescent apparatus is transported to the repairing machine to a repairing process. In such a case, the defect is radiated with the beam generated by the beam generator, thus isolating the defect.

In view of the previously mentioned detection and repairing processes, it is necessary to check the enlarged images of the pixels of the organic electroluminescent apparatus for finding out the locations of the defects. However, this check method is by manpower and is time consumptive, and some defects may be undetected due to artificial carelessness. In addition, the organic electroluminescent apparatus must be transported from the detection machine to the repairing machine for the consequent repairing process when the defects are detected. In practice, the detected defect(s) of the organic electroluminescent apparatus cannot be repaired directly because the organic electroluminescent apparatus is transported from the detection machine to the repairing machine. As with the prior process, the organic electroluminescent apparatus is scanned again in order to locate and then repair the defect.

As mentioned above, a foreign particle exists on the pixel may induce the stacking problem, and further induce a short circuit. However, the defect caused by this particle can be ignored and is unnecessary to be repaired if the particle is smaller than a certain size and the short-circuited issue does not occur. In the conventional detection process, the defect is detected with the optical microscope by way of scanning. This method, however, cannot determine whether the defect will cause the short-circuited issue or not, and as a result, all detected defects will be repaired during the repairing process. In other words, the conventional technology will scan an organic electroluminescent apparatus, locate defects, scan the device again, locate the defects again, and then repair all the detected defects, resulting in wasting time and resources in the manufacturing processes.

It is therefore an important subject of the invention to efficiently detect and repair defects of an organic electroluminescent apparatus.

### SUMMARY OF THE INVENTION

In view of the foregoing, the invention is to provide a system and a method of detection and repair, which can efficiently detect and repair the defect(s) of an organic electroluminescent apparatus.

To achieve the above, a system of detection and repair of the invention comprises a microscope, an image-retrieving device, a current detector, a controller, and a beam generator. In the invention, the microscope enlarges an image of a detected region located on the organic electroluminescent apparatus. The image-retrieving device connected to the microscope for retrieving the image enlarged by the microscope. The current detector connected to the microscope for detecting a location of a defect having abnormal current distribution in the image. The controller connected to the image-retrieving device and the current detector respectively for storing the image retrieved by the image-retrieving device and the location of the defect detected by the current detector. In addition, the controller generates a first control signal according to the image and the location of the defect. The beam generator connected to the controller and the microscope for generating a beam according to the first control signal for isolating the defect.

In addition, the invention also discloses a system of detection and repair, comprising a precise distance measurement device, a controller, a current detector, and a beam generator, for detecting and repairing an organic electroluminescent apparatus. The precise distance measurement device automatically detects a location of the organic electroluminescent apparatus. The controller connected to the precise distance measurement device and the controller generates a third control signal for adjusting the relative positions of the current detector and the organic electroluminescent apparatus according to the detecting location of the precise distance measurement device. The current detector detects a location of a defect having abnormal current distribution, and the controller generates a fourth control signal according to the detected location of the defect. The beam generator connected to the controller and generates a beam for isolating the defect according to the fourth control signal.

To achieve the above, a method of detection and repair, which is for detecting and repairing an organic electroluminescent apparatus, comprises the following steps of: using a microscope to enlarge an image of a detected region located on the organic electroluminescent apparatus; using an image-retrieving device to retrieve the enlarged image; charging the detected region with a bias, and using a current detector to detect a location of a defect having abnormal current distribution in the image; using a controller to store the image and the location of the defect and to generate a first control signal according to the image and the location of the defect; and using a beam generator to generate a beam for isolating the defect according to the first control signal.

In addition, the invention also discloses a method of detection and repair, comprising the following steps of: using a precise distance measurement device to automatically detect a location of the organic electroluminescent apparatus; using a controller to generate a third control signal according to the detecting location of the precise distance measurement device; adjusting the relative positions of the current detector and the organic electroluminescent apparatus and/or the distance between the current detector and the organic electroluminescent apparatus according to the third control signal; charging a bias to the detected region of the organic electroluminescent apparatus; using a current detector to detect a location of a defect having abnormal current distribution; using the controller to generate a fourth control signal according to the detected location of the defect; and using a beam generator to generate a beam for isolating the defect according to the fourth control signal.

As mentioned above, the system and method of detection and repair of the invention, in advance, uses the microscope and image-retrieving device to enlarge and retrieve the image of the detected region on the organic electroluminescent apparatus, or uses the precise distance measurement device and controller to automatically adjust the relative positions of the organic electroluminescent apparatus and the current detector or the distance therebetween. Then, the detected region of the organic electroluminescent apparatus is charged with a bias, so that the current detector can detect the location of the defect having abnormal current distribution. Finally, the beam is generated to isolate the defect. Therefore, it is unnecessary to apply a conventional detection machine and a conventional repairing machine to perform the detecting and repairing processes. Besides, the organic electroluminescent apparatus to be detected and repaired can be automatically aligned. Thus, the possible errors caused by artificial operations and the waste of manpower sources can be efficiently reduced. Moreover, the invention is to detect the abnormal current distribution for detecting the location of the defect, so that the location of the defect can be found out quickly and correctly. As a result, the defects of the organic electroluminescent apparatus can be detected and repaired efficiently.

### BRIEF DESCRIPTION OF THE DRAWINGS

The invention will become more fully understood from the detailed description given herein below illustration only, and thus is not limitative of the present invention, and wherein:

FIG. 1 is a schematic view showing a system of detection and repair according to a preferred embodiment of the invention;

FIG. 2 is a schematic view of the system of detection and repair shown in FIG. 1, which further comprises a stage;

FIG. 3 is a schematic, illustration showing a specific pixel when uses the system of detection and repair of the invention to detect and repair the defect;

FIG. 4 is a schematic view showing a system of detection and repair according to another preferred embodiment of the invention;

FIG. 5 is a flowchart showing a method of detection and repair according to a preferred embodiment of the invention; and

FIG. 6 is a flowchart showing a method of detection and repair according to another preferred embodiment of the invention.

### DETAILED DESCRIPTION OF THE INVENTION

The present invention will be apparent from the following detailed description, which proceeds with reference to the accompanying drawings, wherein the same references relate to the same elements.

The system and method of detection and repair according to the preferred embodiments of the invention will be described herein below with reference to the accompanying drawings, wherein the same reference numbers refer to the same elements. To be noted, the organic electroluminescent apparatuses described in the following comprise organic electroluminescent panels and organic electroluminescent devices.

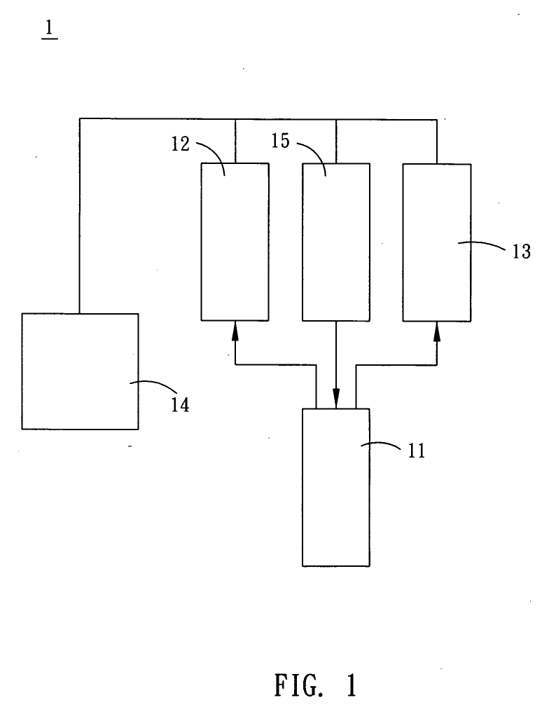

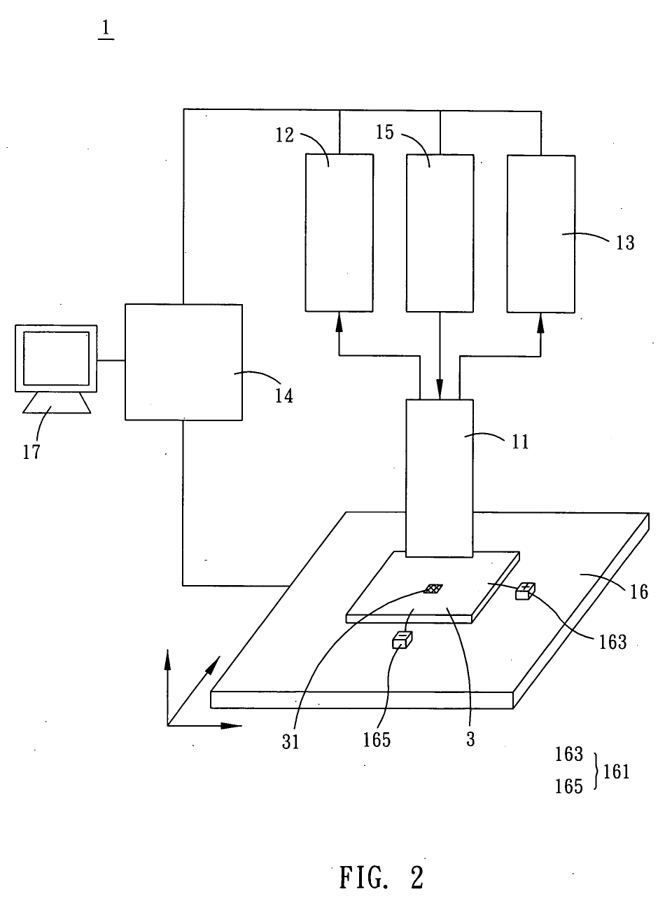

With reference to FIG. 1 and FIG. 2, a system of detection and repair 1 according to a preferred embodiment of the invention comprises a microscope 11, an image-retrieving device 12, a current detector 13, a controller 14, and a beam generator 15.

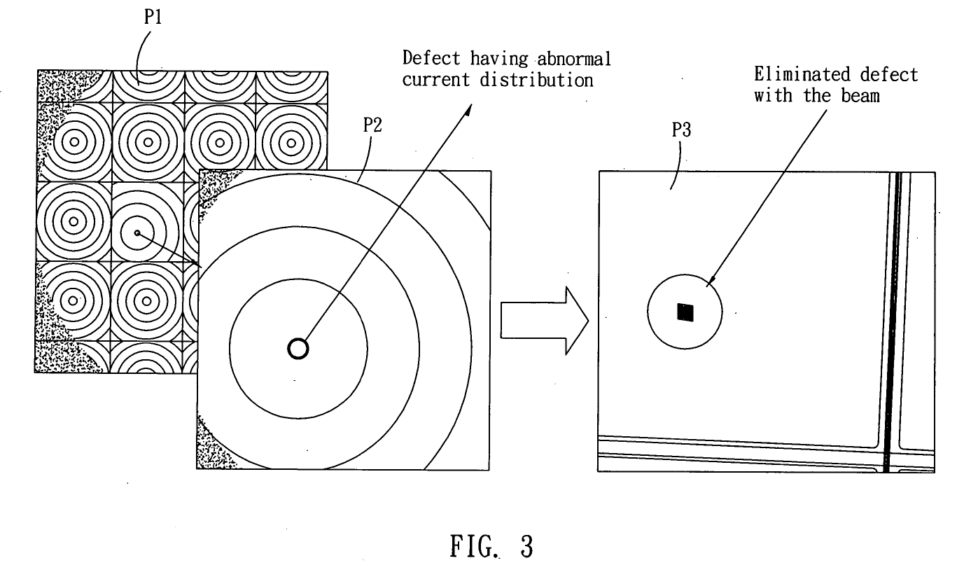

The microscope 11 is used to enlarge an image of a detected region in an organic electroluminescent apparatus 3. The image-retrieving device 12 connects to the microscope 11 and retrieves the image P1 enlarged by the microscope 11 shown in FIG. 3. In the present embodiment, the image-retrieving device 12 is a CCD camera.

The current detector 13 connects to the microscope 11 and detects a location of a defect having abnormal current distribution, as the reference number P2 shown in FIG. 3, in the enlarged image. The controller 14 electrically connects to the image-retrieving device 12 and the current detector 13, respectively. The controller 14 can store the enlarged image retrieved by the image-retrieving device 12, and the location of the defect detected by the current detector 13. Then, the controller 14 generates a first control signal according to the enlarged image and the location of the defect. In the embodiment, the controller 14 is a computer. The current detector 13 can be an infrared (IR) current detector for correctly detecting the current distribution of the detected region on the organic electroluminescent apparatus 3. Accordingly, the location having abnormal current distribution in the detected region can be detected.

The beam generator 15 connects to the controller 14 and the microscope 11 and generates a beam, which goes through the microscope 11, for isolating the defect according to the first control signal. Accordingly, the defect located in the detected region of the organic electroluminescent apparatus can be repaired. The image of reference number P3 shown in FIG. 3 illustrates the repaired defect.

As shown in FIG. 2, the system 1 may further comprise a stage 16, on which the organic electroluminescent apparatus 3 is placed. As shown in FIG. 2, the stage 16 has a power supply 161, which includes a positive terminal 163 and a negative terminal 165. During the current detection for abnormal current distribution, the power supply 161 provides a negative bias or a low forward bias to charge the organic electroluminescent apparatus 3. In the current embodiment, if the defect causes short-circuited of a pixel of the organic electroluminescent apparatus 3, the abnormal current distribution is generated. In this case, the controller 14 further generates a second control signal according to the enlarged image and the location of the defect, and the stage 16 acts according to the second control signal to relatively move the beam generator 15 and the organic electroluminescent apparatus 3. Thus, the location of the defect of the organic electroluminescent apparatus 3 and the beam generator 15 are aligned, such that the beam can focus on the location of the defect. In this embodiment, the state 16 is an XYZ stage.

Moreover, the system of detection and repair 1 may further comprise a display 17, which connects to the controller 14 for showing output data from the controller 14.

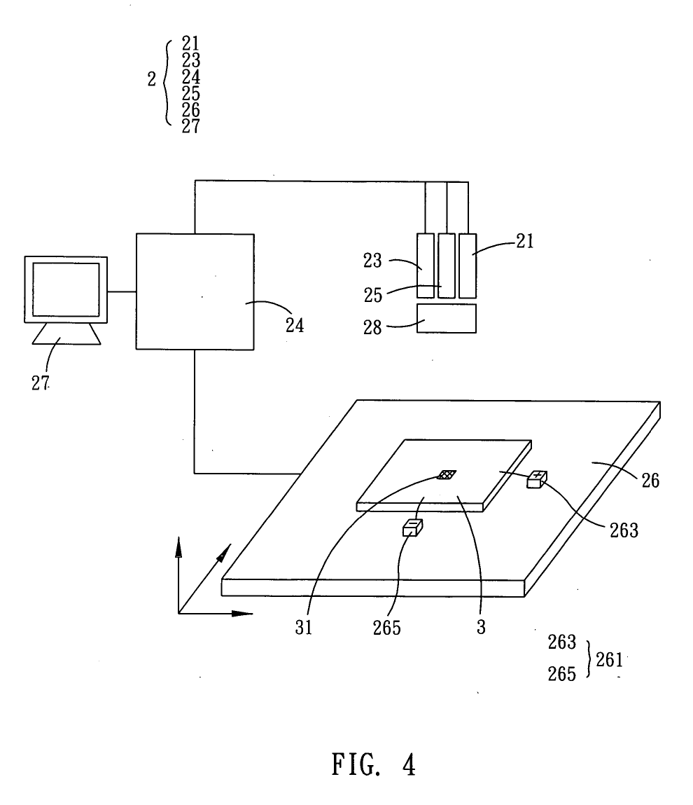

Please refer to FIG. 4. A system of detection and repair 2 according to another preferred embodiment of the invention comprises a precise distance measurement device 21, a current detector 23, a controller 24, a beam generator 25, an optical microscope 28, and a stage 26.

The precise distance measurement device 21 automatically detects the location of an organic electroluminescent apparatus 3. The current detector 23 detects a location 31 of a defect having abnormal current distribution on the organic electroluminescent apparatus 3 (as P2 shown in FIG. 3) through the optical microscope 28. The controller 24 connects to the precise distance measurement device 21, the current detector 23, the optical microscope 28, and the beam generator 25. The controller 24 generates a third control signal for automatically aligning the organic electroluminescent apparatus 3, and the current detector 23 according to the detecting location of the precise distance measurement device 21. In the current embodiment, the precise distance measurement device 21 is a laser distance meter, which outputs a detecting signal such as a laser beam for determining the distance between the organic electroluminescent apparatus 3 and the current detector 23. The controller 24 of the embodiment is a computer. Moreover, the system 2 of the embodiment may further comprise a display 27 connected to the controller 24 for showing output data from the controller 24. Besides, the beam generated by the beam generator 25 can be a laser beam of a specific wavelength such as 532 nm, a radiation beam, an electron beam, or beam of high energy that can eliminate/isolate the defect.

As mentioned above, the precise distance measurement device 21 is used for detecting distance, so that it can assist to modify the distance between the organic electroluminescent apparatus 3 and the current detector 23 (or the optical microscope 28). The precise distance measurement device 21 may use the laser, IR ray or supersonic wave as the signal for measuring the distance. Correspondingly, the precise distance measurement device 21 can be a laser distance meter, an infrared distance meter or ultrasonic distance meter. Of course, the signal for measuring the distance can either emit through the optical microscope 28 or not.

In this embodiment, the optical microscope 28 is a lens mechanism for enlarging the image. The optical microscope 28 is used to detect the image of defects and to transmit the beam for isolating the defect. In this case, the optical microscope 28 may comprise optical lenses of different magnifications or CCD components. The previously mentioned beam generated by the beam generator 25 can focus on the location of the defect through the optical microscope 28 to isolate the defect. To be noted, the dimension of the beam generated by the beam generator 24 can be controlled in advance, so that the beam can directly focus on the location of the defect without passing through the optical microscope 28.

As mentioned above, the stage 26 supports the organic electroluminescent apparatus 3. When receiving the third control signal, the stage 26 interactively moves the organic electroluminescent apparatus 3 and the current detector 23 (or the optical microscope 28) according to the third control signal. In the present embodiment, the stage 28 can move the organic electroluminescent apparatus 3 or the current detector 23 (or the optical microscope 28) only; otherwise, it can move both the organic electroluminescent apparatus 3 and the current detector 23 (or the optical microscope 28). Accordingly, the distance between the organic electroluminescent apparatus 3 and the current detector 23 (or the optical microscope 28) is adjusted. In this embodiment, the state 26 is an XYZ stage. Besides, a three-dimension control mechanism may be added on the optical microscope 28 for adjusting the distance between the organic electroluminescent apparatus 3 and the optical microscope 28. Thus, the location of the defect detected by the current detector 23 and the optical microscope 28 can be aligned with the control of the three-dimension control mechanism.

In addition, the stage 26 has a power supply 261, which includes a positive terminal 263 and a negative terminal 265. During the current detection for abnormal current distribution, the power supply 261 provides a negative bias or a low forward bias to charge the organic electroluminescent apparatus 3. In the current embodiment, the abnormal current distribution is generated if the defect causes short-circuited of a pixel of the organic electroluminescent apparatus 3. In this case, the controller 14 further generates a fourth control signal and a fifth control signal according to the enlarged image and the location of the defect. Then, the stage 26 and the beam generator 25 respectively act according to the fifth control signal and the fourth control signal. In details, the stage 26 interactively moves the beam generator 25 (and/or the optical microscope 28) and the organic electroluminescent apparatus 3 according to the fifth control signal. Accordingly, the beam generator 25 may align to the location 31 of the defect of the organic electroluminescent apparatus 3 (through the optical microscope 28). After that, the beam generator 25 generates a beam according to the fourth control signal. The generated beam then focuses on the location 31 of the defect to eliminate/isolate the defect so as to repair the defect in the detected region of the organic electroluminescent apparatus.

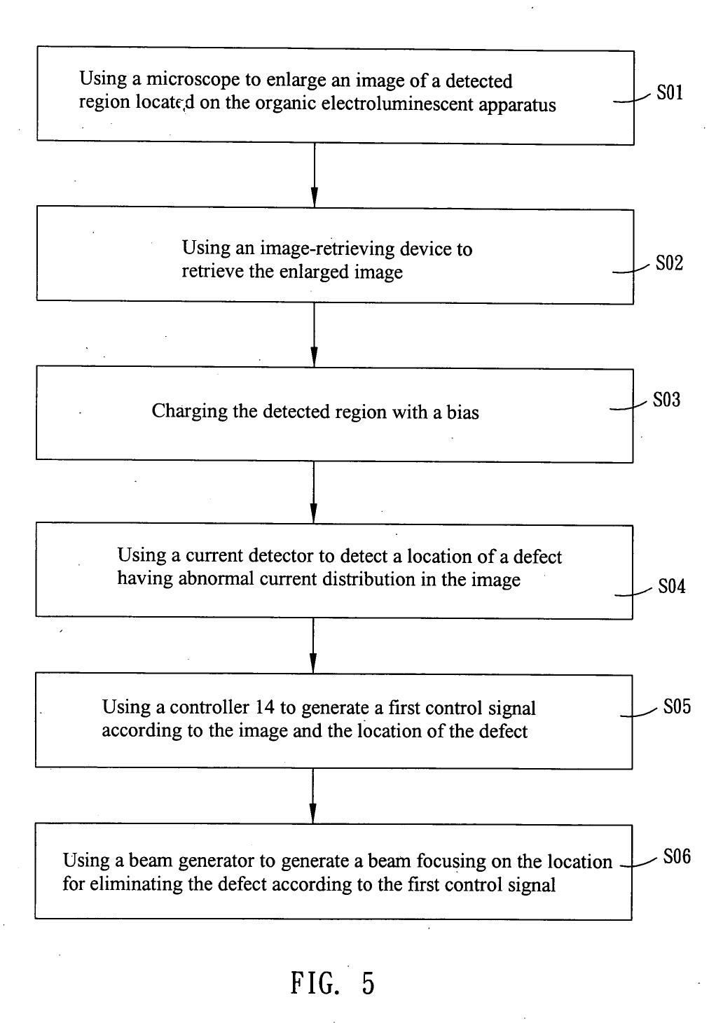

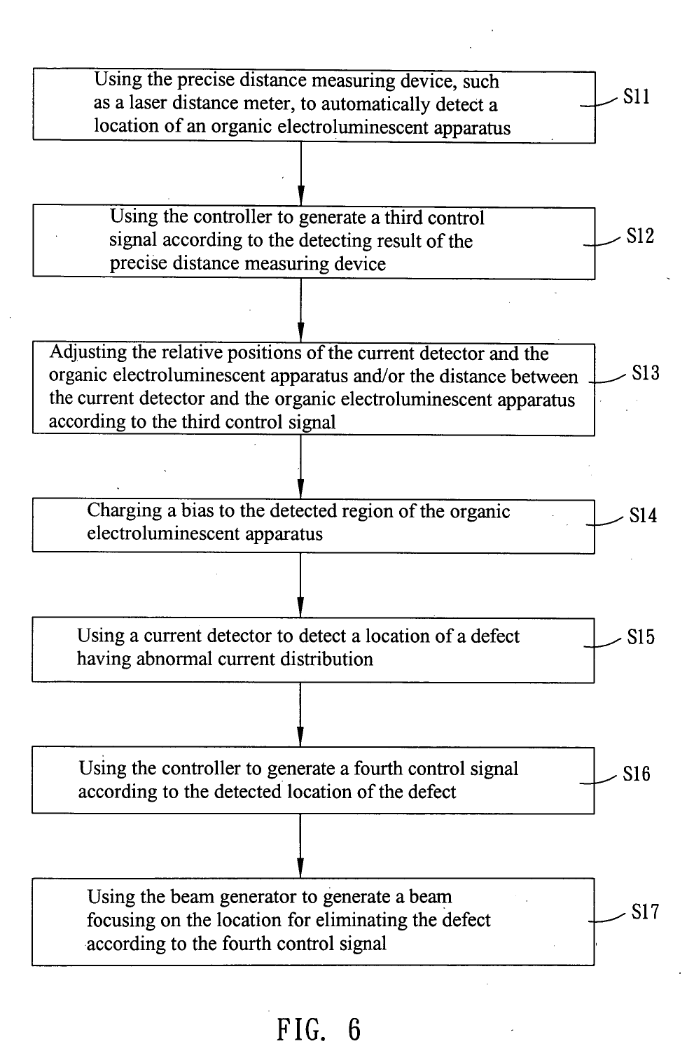

With reference to FIG. 5 and FIG. 6, a method of detection and repair according to a preferred embodiment of the invention will be described hereinafter. The method of detection and repair is applied in the previously mentioned system 1 or 2 for detecting and repairing an organic electroluminescent apparatus 3.

As shown in FIG. 5, a method of detection and repair according to a preferred embodiment of the invention comprises the following steps of: using a microscope 11 to enlarge an image of a detected region located on the organic electroluminescent apparatus 3 (step S01); using an image-retrieving device 12 to retrieve the enlarged image (step S02); charging the detected region with a bias (step S03); using a current detector 13 to detect a location 31 of a defect having abnormal current distribution in the image (step S04); using a controller 14 to generate a first control signal according to the image and the location of the defect (step S05); and using a beam generator 15 to generate a beam focusing on the location 31 for isolating the defect according to the first control signal (step S06).

To align the beam generated by the beam generator 15 precisely to the location 31 on the organic electroluminescent apparatus 3, the controller 14 may further generate a second control signal according to the stored enlarged image and the location of detects. The generated second control signal can drive the stage 16 and the beam generator 15 for relatively moving. Consequently, the location of the defect on the organic electroluminescent apparatus 3 supported on the stage 16 can be aligned with the beam generator 15.

As shown in FIG. 6, a method of detection and repair according to another preferred embodiment of the invention comprises the following steps of: using the precise distance measurement device 21, such as a laser distance meter, to automatically detect a location of an organic electroluminescent apparatus 3 (step S11); using the controller 24 to generate a third control signal according to the detecting location of the precise distance measurement device 21 (step S12); adjusting the relative positions of the current detector 23 and the organic electroluminescent apparatus 3 and/or the distance between the current detector 23 and the organic electroluminescent apparatus 3 according to the third control signal (step S13); charging a bias to the detected region of the organic electroluminescent apparatus 3 (step S14); using a current detector 23 to detect a location 31 of a defect having abnormal current distribution (step S15); using the controller 24 to generate a fourth control signal according to the detected location 31 of the defect (step S16); and using the beam generator 25 to generate a beam focusing on the location 31 for isolating the defect according to the fourth control signal (step S17).

To align the beam generated by the beam generator 25 precisely to the location 31 on the organic electroluminescent apparatus 3, the controller 14 may further generate a fifth control signal to drive the stage 26 and the beam generator 25 for relatively moving. Consequently, the location 31 of the defect on the organic electroluminescent apparatus 3 supported on the stage 26 can be aligned with the beam generator 25. In this case, the organic electroluminescent apparatus 3 and the current detector 23 (or the optical microscope 28) can be relatively moved according to the third control signal, so that the current detector 23 can precisely detect out the location 31 of the defect. After that, the beam generator 25 and the organic electroluminescent apparatus 3 are relatively moved according to the fifth control signal, so that the beam can align to the location 31 of the defect of the organic electroluminescent apparatus 3. Finally, the beam generator 25 outputs the beam according to the fourth control signal. The beam focuses on the location 31 of the defect to eliminate/isolate the defect.

In summary, the system and method of detection and repair of the invention, in advance, uses the microscope and image-retrieving device to enlarge and retrieve the image of the detected region on the organic electroluminescent apparatus. Or, the system and method invention uses the precise distance measurement device and controller to automatically adjust the relative positions of the organic electroluminescent apparatus and the current detector or the distance between the organic electroluminescent apparatus and the current detector. Then, the detected region of the organic electroluminescent apparatus is charged with a bias, so that the current detector can detect the location of the defect having abnormal current distribution. Finally, the beam is generated to isolate the defect. Therefore, it is unnecessary to apply a conventional detection machine and a conventional repairing machine to perform the detecting and repairing processes. Besides, the organic electroluminescent apparatus to be detected and repaired can be automatically aligned. Thus, the possible errors caused by artificial operations and the waste of manpower sources can be efficiently reduced. Moreover, the invention is to detect the abnormal current distribution for detecting the location of the defect, so that the location of the defect can be found out quickly and correctly. As a result, the defects of the organic electroluminescent apparatus can be detected and repaired efficiently.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A system of detection and repair for detecting and repairing an organic electroluminescent apparatus, comprising:
a microscope for enlarging an image of a detected region located on the organic electroluminescent apparatus;
an image-retrieving device connected to the microscope for retrieving the image enlarged by the microscope;
a current detector connected to the microscope for detecting a location of a defect having abnormal current distribution in the image;
a controller connected to the image-retrieving device and the current detector respectively for storing the image retrieved by the image-retrieving device and the location of the defect detected by the current detector, and the controller generates a first control signal according to the image and the location of the defect; and
a beam generator connected to the controller and the microscope for generating a beam according to the first control signal for isolating the defect.

2. The system of claim 1, wherein the current detector is an infrared (IR) current detector.

3. The system of claim 1, wherein the controller further generates a second control signal according to according to the image and the location of the defect stored therein.

4. The system of claim 3, further comprising:
a stage, which has a power supply for charging a bias to the organic electroluminescent apparatus.

5. The system of claim 4, wherein the stage supports the organic electroluminescent apparatus and interactively moves the organic electroluminescent apparatus and the beam generator according to the second control signal for aligning the location of the defect and the beam generator, and the beam focuses on the location of the defect.

6. The system of claim 4, wherein the stage is an XYZ stage.

7. The system of claim 4, wherein the bias is a negative bias or a low forward bias.

8. The system of claim 1, further comprising:
a display connected to the controller for showing output data from the controller.

9. The system of claim 1, wherein the controller is a computer.

10. The system of claim 1, wherein the image-retrieving device is a CCD camera.

11. The system of claim 1, wherein the organic electroluminescent apparatus is an organic electroluminescent panel or an organic electroluminescent device.

12. The system of claim 1, wherein the beam emits through the microscope.

13. The system of claim 1, wherein the beam is a radiation beam, a laser beam or an electron beam.

14. A method of detection and repair for detecting and repairing an organic electroluminescent apparatus, comprising
using a microscope to enlarge an image of a detected region located on the organic electroluminescent apparatus;
using an image-retrieving device to retrieve the image;
charging a bias to the detected region, and using a current detector to detect a location of a defect having abnormal current distribution in the image;
using a controller to store the image and the location of the defect and to generate a first control signal according to the image and the location of the defect; and
using a beam generator to generate a beam according to the first control signal for isolating the defect.

15. The method of claim 14, wherein the image-retrieving device is a CCD camera.

16. A system of detection and repair for detecting and repairing an organic electroluminescent apparatus, comprising:
a precise distance measurement device, which automatically detects a location of the organic electroluminescent apparatus;
a controller, which connects to the precise distance measurement device and generates a third control signal according to the detecting location of the precise distance measurement device;
a current detector, which connects to the controller and detects a location of a defect having abnormal current distribution, wherein the relative positions of the current detector and the organic electroluminescent apparatus and/or a distance between the current detector and the organic electroluminescent apparatus is adjusted according to the third control signal, and the controller generates a fourth control signal according to the detected location of the defect; and
a beam generator, which connects to the controller and generates a beam according to the fourth control signal for isolating the defect.

17. The system of claim 16, further comprising:
a stage, which supports the organic electroluminescent apparatus, wherein the controller further generates a fifth control signal according to the location of the defect, the stage interactively moves the organic electroluminescent apparatus and the beam generator according to the fifth control signal for aligning the location of the defect and the beam generator, and the beam focuses on the location of the defect.

18. The system of claim 17, wherein the stage further has a power supply for charging a negative bias or a low forward bias-to the organic electroluminescent apparatus.

19. The system of claim 16, further comprising:
an optical microscope for enlarging an image of the detected region located on the organic electroluminescent apparatus, wherein the current detector further connects to the optical microscope and detects the location of the defect from the image enlarged by the optical microscope, and the beam generator further connects to the optical microscope for generating the beam emitting through the optical microscope.

20. The system of claim 16, wherein the precise distance measurement device is a laser distance meter.
